(19) United States
(12) Patent Application Publication
(10) Pub. No.: US 2026/0344137 A1
(43) Pub. Date: Oct. 29, 2026

(54) LIGHT SOURCE DEVICE, DISPLAY DEVICE, AND METHOD FOR MOUNTING LIGHT SOURCE DEVICE

(71) Applicant: Nippon Seiki Co., Ltd., Niigata (JP)

(72) Inventor: Hiroyuki Miyabe, Niigata (JP)

(21) Appl. No.: 19/630,941

(22) Filed: Mar. 27, 2026

(30) Foreign Application Priority Data
Apr. 25, 2025 (JP) 2025-073181

(51) Int. Cl. H10H 20/858; G01K 7/02; H10H 20/01; H10H 29/30

(52) U.S. Cl. CPC H10H 20/8585; G01K 7/028; H10H 20/0365; H10H 29/30

(57) ABSTRACT

A light source device having a plurality of light sources provided in a light source mounting region on a mounting surface of a circuit board, at least one temperature detection unit provided outside the light source mounting region on the mounting surface, and a thermal pattern having a main part that collects heat generated by light emission of at least one light source at an arbitrary position, among the plurality of light sources, and a connection part that is thermally connected to the temperature detection unit and transmits heat from the main part to the temperature detection unit, wherein the circuit board includes a surface layer on which the plurality of light sources are mounted, and at least one inner layer provided below the surface layer via an electrical insulating film, and the main part of the thermal pattern is provided in the inner layer so as to overlap the light source mounting region in a plan view seen from above.

### TECHNICAL FIELD

The present invention relates to a light source device, a display device, a method for mounting the light source device, and the like.

### BACKGROUND ART

Patent Document 1 discloses a display device that performs suppression processing to suppress changes in display caused by temperature changes in a display panel.

FIG. 2 of this Patent Document 1 shows a configuration in which a backlight temperature detection unit for detecting the temperature of a backlight provided on the back surface of a liquid crystal panel is provided in the center (central part) of a backlight arrangement region.

Furthermore, FIG. 6 of Patent Document 1 shows a system configuration when performing the above-mentioned suppression processing in a display device that performs local dimming driving.

### PRIOR ART DOCUMENT

### Patent Document

Patent Document 1: Japanese Unexamined Patent Application Publication No. 2014-149485

### SUMMARY OF INVENTION

### Technical Problem

Investigations by the present inventor have revealed the following problems.
(1) For example, in the case of measuring the temperature of a backlight unit (specifically, for example, an LED substrate on which light-emitting diodes (LEDs) as light sources are mounted) in an in-vehicle display device, conventionally, one surface-mount type thermistor (broadly speaking, a temperature detection unit) has been used to observe the temperature of the LED substrate heated by the lit LEDs.

In the configuration example of the light source device described in FIG. 2 of the above-mentioned Patent Document 1, one thermistor is disposed as a backlight temperature detection unit in the center (central part) of the arrangement region of the LEDs as light sources.

However, in recent years, higher integration of light sources on LED substrates has progressed, and along with this, it may become difficult to secure space for disposing a thermistor in the center of the LED substrate.
(2) For example, in an LED substrate in a display device employing a local dimming driving method, the LED mounting region is divided into a plurality of regions, and it is necessary to provide a thermistor for each divided region; therefore, it becomes difficult to secure space for disposing the thermistor.

Specifically, since the mounting pitch between each LED becomes narrow, it is not easy to secure a mounting region for a thermistor in each divided region.

In addition, a light box (including a reflector, etc.) may be disposed on the LED mounting region so as to surround each LED, and in this case, securing space for disposing a thermistor becomes even more difficult.
(3) Furthermore, when a local dimming driving method is adopted, it is possible to individually light LEDs at arbitrary positions according to the displayed image. In other words, the position of the LEDs serving as heat sources changes according to the displayed image, and there may be cases where heat generation by the LEDs locally increases in a part of the LED substrate.

Therefore, for example, it becomes difficult to observe the accurate temperature rise of the entire LED substrate with one thermistor.

In other words, when a local dimming driving method is adopted, LEDs at arbitrary positions are lit in accordance with the displayed image; therefore, for example, when the lighting rate of LEDs at positions far from the thermistor is concentrated, heat is not sufficiently transferred to the thermistor, so there is a possibility that the thermistor measures a temperature lower than the actual temperature of the LED substrate. Since heat generation countermeasure processing is performed based on the measurement result with such large errors, there is no denying that the implementation timing of heat generation countermeasures may be delayed, or the accuracy of the heat generation countermeasure processing may decrease.
(4) As a countermeasure against the problem of (3) above, for example, there is an idea to dispose a thermistor on the back surface of the LED substrate, but in this case, the thermistor comes into contact with a heat sink provided directly under the LED substrate, and since the heat is dispersed by the heat sink, it is difficult to measure the accurate temperature rise of the LED substrate.
(5) As another countermeasure, there is an idea to dispose thermistors at the four corners of the LED mounting region (assuming a rectangular mounting region here), calculate a parameter obtained by 4-point averaging based on the detection results of a total of four thermistors, or calculate a parameter obtained by multiplying each measurement value by a correction coefficient to perform control of LED heat generation, etc.

However, in this case, when only the LEDs disposed in the center of the LED arrangement region emit light and generate heat, those LEDs are at the farthest distance from any of the thermistors provided at the four corners, and therefore, a problem arises that it is difficult to measure the accurate temperature rise.
(6) As described above, it is not easy to provide a thermistor within the LED arrangement region, and even as a countermeasure, when mounting a thermistor at a position away from the LEDs (when disposing a plurality of thermistors outside the arrangement region), if only the LEDs at positions far from each thermistor are lit intensively, the thermistor may observe a lower temperature even if the temperature of the lit part is at a temperature requiring temperature control, causing a problem that appropriate temperature control becomes difficult.

The present invention has been made based on the above investigation results, and one of its objects is to enable simplification of the mounting of a temperature detection unit and improvement in the accuracy of temperature measurement in a light source device.

Other objects of the present invention will become apparent to those skilled in the art by referring to the aspects and best embodiments exemplified below and the accompanying drawings.

### Solution to Problem

In order to easily understand the outline of the present invention, aspects according to the present invention are exemplified below.

In a first aspect, a light source device comprises a plurality of light sources provided in a light source mounting region on a mounting surface of a circuit board, at least one temperature detection unit provided outside the light source mounting region on the mounting surface, and a thermal pattern including a main part that collects heat generated by light emission of at least one light source at an arbitrary position, among the plurality of light sources, and a connection part that is thermally connected to the temperature detection unit and transmits heat from the main part to the temperature detection unit. A direction perpendicular to the mounting surface of the circuit board is defined as a vertical direction, a direction toward the mounting surface is defined as an upward direction, and a direction opposite to the upward direction is defined as a downward direction. Given the definition above, the circuit board includes a surface layer on which the plurality of light sources are mounted, and at least one inner layer provided below the surface layer via an electrical insulating film, and the main part of the thermal pattern is provided in the inner layer so as to overlap the light source mounting region in a plan view seen from above.

According to the first aspect, a thermal pattern (also called thermal wiring) for temperature transmission is provided in an inner layer of a circuit board. As this thermal pattern, for example, copper (or an alloy with nickel, iron, etc.) having excellent thermal conductivity can be used.

Also, for example, the main part of the thermal pattern can be provided directly under each light source (for example, each LED) (in this case, in a plan view seen from above, at least a part of the thermal pattern will have an overlap with the light source (LED, etc.)).

Therefore, even if the position of the temperature detection unit and the position of the light source (LED, etc.) as a heat source are separated, heat generated from the light source (LED, etc.) can be efficiently collected through the electrical insulating layer and efficiently (in other words, reducing heat loss) transmitted to the temperature detection unit by the thermal pattern.

Therefore, even if the temperature detection unit is disposed outside the light source mounting region, the temperature of the circuit board (mounting board) can be measured (detected) with high accuracy. Therefore, in a light source device, it becomes possible to simplify the mounting of a temperature detection unit and improve the accuracy of temperature measurement.

In a second aspect dependent on the first aspect, in a plan view seen from above, the main part of the thermal pattern has a planar shape, and the main part of the thermal pattern having the planar shape has an overlap with each of the plurality of light sources, or, in a plan view seen from above, the main part of the thermal pattern has a plurality of branch wirings branched from the connection part, and each of the plurality of branch wirings has an overlap with a part or all of a first light source, among the plurality of light sources, which is located above that branch wiring in a relative positional relationship with the first light source, and a second light source among the plurality of light sources that is not located above that branch wiring and does not have an overlap with the branch wiring may be arranged so that the shortest distance between each of the second light sources and the branch wiring is the same, or that the shortest distance is within a predetermined tolerance range.

In the second aspect, the main part of the thermal pattern is planar (solid pattern) and may have an overlap with each light source positioned above it, and also has a plurality of branch wirings (also called branch lines or branch patterns) branched from the connection part, and when the light source positioned above each branch wiring is a first light source, a part or all of each branch wiring has an overlap with the first light source disposed corresponding to each branch wiring. Therefore, efficient heat collection is realized for the first light source.

In addition, in the case where the light source that is not located above that branch wiring among the plurality of light sources and does not have an overlap with the branch wiring is a second light source, they are arranged such that the shortest distance between each of the second light sources and the branch wiring is the same, or the shortest distance falls within a predetermined tolerance range.

This can be rephrased as meaning that for the above-mentioned “second light source”, the variation in the shortest distance between each light source and the branch wiring of the thermal pattern in a plan view seen from above falls within a predetermined tolerance range.

Therefore, it is possible to suppress (for example, minimize) the variation in heat collection property when the branch wiring collects heat generated from each light source. Therefore, even if each light source were to emit light and generate heat independently, the heat of that light source can be transmitted to the temperature detection unit with high accuracy (in other words, accurately).

For example, even if light sources in a partial region at an arbitrary position in the light source mounting region emit light locally, the temperature rise of the circuit board (mounting board) due to that local heat generation can be detected with high accuracy (accurately) regardless of the relative positional relationship between the partial region and the light source mounting region (in other words, regardless of where the partial region is in the light source mounting region).

According to this aspect, the temperature rise of the circuit board due to heat generation of the light source can be detected with high accuracy (accurately) regardless of the position where the light source is disposed, and therefore, it becomes possible to perform highly accurate countermeasure processing capable of suppressing the temperature rise at an appropriate timing.

In a third aspect dependent on the second aspect, in the case where the main part of the thermal pattern has the plurality of branch wirings, each of the plurality of branch wirings may have a linear or curved shape in a plan view seen from above.

In this aspect, the branch wirings as the main part of the thermal pattern can be linear or curved.

Although light sources (LEDs, etc.) are disposed on the mounting surface of the circuit board, no light sources are disposed in the inner layer of the circuit board, and since there is much empty space, there is a high degree of freedom in disposing the thermal pattern. Therefore, the shape of the pattern with high heat collection and heat transfer performance can be selected in consideration of the state of mounting of the light sources, for example, the shape of the light source mounting region, the arrangement of light sources, the density of the arrangement of light sources, and the arrangement situation of signal lines and grounds (both are surface layer patterns) that supply signals to the light sources.

Therefore, the shape, etc., of the thermal pattern in a plan view seen from above (specifically, the width and length of straight lines, the degree of bending, width, and length of curves, etc.) can also be determined relatively freely.

In a fourth aspect dependent on the first or second aspect, the light source mounting region has a rectangular shape in a plan view seen from above, the plurality of light sources are arranged in a matrix in the light source mounting region, the plurality of light sources arranged in the matrix can be expressed by an m-row n-column (m is an integer of 4 or more, n is an integer of 2 or more) matrix, and in the matrix, the linear branch wirings may overlap only with each of the light sources arranged corresponding to rows of the matrix whose row number m is a multiple of 2 in a plan view seen from above.

In the fourth aspect, the arrangement of each light source is expressed as an m-row n-column matrix (m is an integer of 4 or more, n is an integer of 2 or more), and linear branch wirings are disposed such that all or a part (preferably all) of each branch wiring, which is the main part of the thermal pattern, overlaps only with light sources corresponding to the m-th rows of the matrix whose row number m is a multiple of 2 (for example, when m is 2, the 2nd row, 1st column matrix).

The light sources corresponding to the m-th row of the matrix where m is a multiple of 2 in this case correspond to the “first light source” in the third aspect described above. The branch wiring, which is the main part of the thermal pattern, exists directly under the light sources corresponding to the rows of the matrix of the 2nd row, 4th row (the same applies hereinafter), and for those light sources, the heat generated from each light source is transmitted to the main part of the thermal pattern at the shortest distance via the electrical insulating film, so that efficient heat collection is realized.

On the other hand, the light sources corresponding to the rows of the matrix of the 1st row, 3rd row, 5th row (the same applies hereinafter) correspond to the “second light source” in the third aspect described above. In a plan view seen from above, the shortest distance between each light source and the branch wiring disposed in the vicinity is, for example, the same (equidistant) because each light source is arranged regularly, and each light source is equally disposed in the vicinity of the branch wiring, so that there is no variation regarding heat collection for each light source, and efficient heat collection is possible for any light source.

Also, there may be a case where a slight difference occurs in the above-mentioned shortest distance due to some circumstances (for example, layout convenience with other wirings (ground lines or signal lines)). However, as long as the variation in each shortest distance is within a predetermined tolerance range, it is possible to suppress (for example, minimize) the variation in heat collection property when the branch wiring of the thermal pattern collects heat generated from each light source.

Note that although the distance between each light source and the temperature detection unit changes according to the position of each light source, the thermal pattern is composed of a material with high thermal conductivity, so the variation in the length of the branch wiring of the thermal pattern can be ignored.

Therefore, according to this aspect, the temperature rise of the circuit board (or each light source) due to heat generation of the light source can be detected with high accuracy (accurately) regardless of the position where the light source is disposed, and therefore, it is possible to perform highly accurate countermeasure processing capable of suppressing the temperature rise at an appropriate timing.

In a fifth aspect dependent on any one of the first to fourth aspects, the light source mounting region is divided into a plurality of rectangular divided regions so as to correspond to local dimming driving of the plurality of light sources, in each of the divided regions, the temperature detection unit is disposed outside a predetermined end portion of that divided region, and an end portion of the connection part of at least one thermal pattern on the temperature detection unit side may be thermally connected to the temperature detection unit.

In the fifth aspect, the present invention is applied to a light source device of a display device employing a local dimming driving method. As explained above, in the conventional technology, when adopting a local dimming driving method, light sources at arbitrary positions are lit in accordance with the displayed image, so if the position of the light source emitting light is far from the temperature detection unit, heat may not be sufficiently transferred to the temperature detection unit, potentially delaying the implementation timing of heat generation countermeasures or decreasing the accuracy of the heat generation countermeasure processing. According to this aspect, the above-mentioned problem is resolved. Also, in this aspect, since heat can be efficiently transmitted to the temperature detection unit via the thermal pattern with high thermal conductivity, the temperature detection unit can be disposed outside a predetermined end portion of the light source mounting region, and the layout related to the arrangement of the temperature detection unit and the like is also simplified.

Note that the predetermined end portion (or predetermined boundary line) can be specifically one of the four sides of the rectangle (quadrilateral), or the vicinity of that side.

In a sixth aspect dependent on any one of the first to fifth aspects, a ground for grounding each of the plurality of light sources includes a ground plane with a wide wiring width and a ground line that branches from the ground plane and has a wiring width narrower than that of the ground plane, and the ground plane is not provided around the main part of the thermal pattern, and is provided at a position away from the main part of the thermal pattern within the light source mounting region, or may be provided outside the light source mounting region.

In the sixth aspect, the ground plane (planar ground bus) is not provided around the main part of the thermal pattern (vicinity of the periphery), and is provided, for example, in an empty region away from the thermal pattern (main part of the thermal pattern) within the light source mounting region; or provided outside the light source mounting region.

As a result, it is prevented that heat generated by the light source escapes to the wide ground plane. Since the heat of the light source is efficiently transmitted to the main part of the thermal pattern without escaping to the ground plane, there is no decrease in heat collection by the main part of the thermal pattern, and high heat collection is always realized.

In a seventh aspect dependent on any one of the first to sixth aspects, a cathode electrode of an LED as the light source, for each of the light sources, may be provided under that light source as a surface layer pattern provided on the surface layer.

In the seventh aspect, a cathode electrode of the LED (broadly speaking, a light-emitting element or a light source element) as a surface layer pattern is provided under each light source mounted on the mounting surface. This cathode electrode also functions as a heat dissipation member that dissipates heat generated by each light source toward the main part of the thermal pattern disposed directly below. Therefore, the heat collection in the main part of the thermal pattern is improved.

In an eighth aspect dependent on any one of the second to seventh aspects, in a plan view seen from above, the thickness of the branch wiring as the main part of the thermal pattern may be set narrower than the width of each of the plurality of light sources in a direction corresponding to the thickness of the branch wiring.

In the eighth aspect, the width of the branch wiring as the main part of the thermal pattern is set narrower than the width of each light source (light source device) in that width direction.

In recent years, higher integration of each light source has progressed, and the pitch of each light source tends to become narrower. Also, there is a possibility that wiring for connection with a ground plane or signal line, or through-vias (or contact electrodes) may be provided at arbitrary positions in the inner plane of the circuit board.

Even in such a case, according to this aspect, since the width of the branch wiring as the main part of the thermal pattern is set narrower than the width of each light source (each light source device), the exclusive area of the thermal pattern becomes small, so it is possible to dispose the branch wiring relatively freely in response to the narrowing pitch of each light source or the decrease in the degree of freedom in the arrangement of the branch wiring in the inner layer of the circuit board.

In a ninth aspect dependent on any one of the first to eighth aspects, on the mounting surface of the circuit board, a light source control unit that controls driving of the plurality of light sources is provided in addition to the light source mounting region, and one or a plurality of the temperature detection units may be provided in an empty region between the light source mounting region and the light source control unit.

In this aspect, it is assumed that a light source control unit is provided on the mounting surface of the circuit board. One or a plurality of temperature detection units (in other words, at least one temperature detection unit) are provided in an empty region (empty space) between the light source mounting region and the light source control unit on the mounting surface. According to this aspect, heat generated in the light source mounting region can be efficiently transmitted to the temperature detection unit using a thermal pattern with high thermal conductivity, and furthermore, that heat can be efficiently transmitted to the light source control unit provided in the vicinity of the temperature detection unit.

Therefore, based on highly accurate temperature detection results, highly accurate countermeasure processing for temperature suppression can be performed at an appropriate timing.

Also, in this aspect, since an empty region in the circuit board is effectively used, mounting of devices with high integration (in other words, a small circuit board with little useless empty space) can be realized.

In a tenth aspect dependent on any one of the first to ninth aspects, a multilayer FR-4 substrate is used as the circuit board, and the multilayer FR-4 substrate may be capable of having a conductive through-member that penetrates each layer.

In this aspect, a multilayer (for example, 4-layer) FR-4 substrate is used. An FR-4 substrate is a circuit board whose main materials are glass fiber cloth and epoxy resin, and has excellent properties in electrical insulation, mechanical strength, thermal stability, flame retardancy, etc.

Therefore, the FR-4 substrate contributes to efficient heat conduction by the thermal pattern, and can also suppress thermal instability of the circuit board caused by providing the thermal pattern, and ensure stable heat detection characteristics.

In this aspect, this FR-4 substrate can be made multilayered, and a through-member (specifically, a through-via, or a contact electrode embedded in a contact hole, etc.) can be formed on the multilayered substrate.

In recent years, higher integration of light sources (light source elements) has progressed, and from the viewpoint of removing thermal instability in addition to electrical connection to the light source elements, considerable constraints have arisen regarding the layout of wiring (conductive pattern). Even when the degree of freedom in the layout of wiring (conductive pattern) decreases, according to this aspect, by effectively using the inner layer patterns of the multilayer circuit board (for example, upper patterns and lower patterns can be provided), it is possible to relatively freely lay out the thermal pattern while eliminating thermal instability. Therefore, it is possible to respond relatively easily to higher integration of light sources.

In an eleventh aspect, a display device comprises the light source device according to any one of the first to tenth aspects, and a display unit that displays an image using light emission of the light source device.

According to this aspect, it is possible to realize a display device equipped with a light source device (light source unit) capable of effectively protecting the light source (light source in the backlight unit) from deterioration of light emission characteristics or damage to the device due to thermal factors.

In a twelfth aspect, a method for mounting a light source device includes the steps of providing a plurality of light sources in a light source mounting region on a mounting surface of a circuit board, providing at least one temperature detection unit outside the light source mounting region on the mounting surface, and providing a thermal pattern including a main part that collects heat generated by light emission of at least one light source at an arbitrary position, among the plurality of light sources, and a connection part that is thermally connected to the temperature detection unit and transmits heat from the main part to the temperature detection unit. A direction perpendicular to the mounting surface of the circuit board is defined as a vertical direction, a direction toward the mounting surface is defined as an upward direction, and a direction opposite to the upward direction is defined as a downward direction. Given the definition above, in the case where the circuit board includes a surface layer on which the plurality of light sources are mounted, and at least one inner layer provided below the surface layer via an electrical insulating film, the step of providing the thermal pattern includes providing the main part of the thermal pattern in the inner layer so as to overlap the light source mounting region in a plan view seen from above.

According to this aspect, it is possible to realize a display device having a light source device in which heat generation countermeasures for the light source are sufficiently implemented.

Those skilled in the art will easily understand that the exemplified aspects according to the present invention can be further modified without departing from the spirit of the present invention.

### BRIEF DESCRIPTION OF DRAWINGS

FIG. 1 is a diagram showing an example of the overall configuration of a display device including a light source device.

FIG. 2 is a diagram showing an example of a configuration for driving each light source (LED) in a light source device employing a local dimming driving method.

FIG. 3 is a diagram showing an example of a configuration of a circuit that controls temperature in a case where a thermistor is used as a temperature detection unit and a cooling element is used for temperature suppression.

FIG. 4 is a diagram showing an example of a layout configuration on a mounting surface of a circuit board in which a configuration for transmitting heat to a temperature detection unit using a thermal pattern is adopted.

FIG. 5 is a diagram showing an example of the arrangement of a ground pattern, anode electrodes and cathode electrodes of LEDs, etc., in the layout configuration of FIG. 4 (layout configuration corresponding to local dimming driving).

FIG. 6 is a cross-sectional view taken along line A-A′ in FIG. 5.

FIG. 7 is a diagram showing examples of patterns disposed in each layer of a 4-layer FR-4 substrate.

FIG. 8 is a diagram showing an example of a layout in which branch wirings as the main part of a thermal pattern are curved.

### DESCRIPTION OF EMBODIMENTS

The best embodiment described below is used for easily understanding the present invention. Therefore, those skilled in the art should note that the present invention is not unduly limited by the embodiment described below.

### First Embodiment

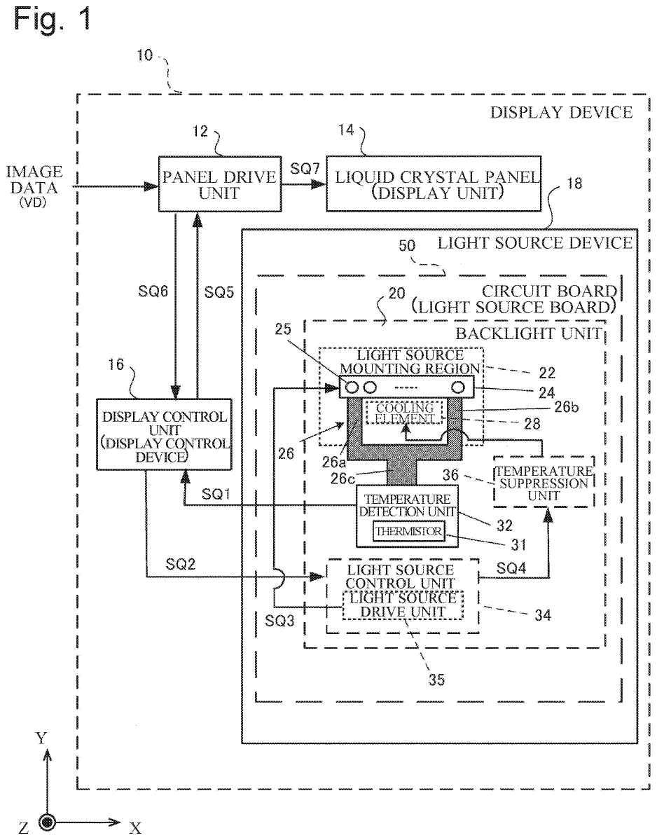

Referring to FIG. 1. FIG. 1 is a diagram showing an example of the overall configuration of a display device including a light source device.

In FIG. 1, the left-right direction on the paper (in other words, the circuit board 50) is referred to as the X direction, the vertical direction perpendicular to this X direction is referred to as the Y direction, and the vertical direction (direction perpendicular to the paper or the mounting surface of the circuit board 50), which is perpendicular to both the X direction and the Y direction, is sometimes referred to as the Z direction. Also, regarding the vertical direction, a direction toward the mounting surface is sometimes referred to as the upward direction (+Z direction), and a direction opposite to the upward direction is sometimes referred to as the downward direction (−Z direction).

Also, in the following description, the expression “plan view seen from above (+Z direction)” is used, but the “plan view” above can be rephrased as “transparent plan view (in a transparent plan drawing)”. Specifically, for example, it is a plan view of a thermal pattern when the thermal pattern provided under an electrical insulating layer is seen through the electrical insulating layer from the upper side.

In FIG. 1, a display device 10 includes a panel drive unit 12 to which image data VD is input, a liquid crystal panel (hereinafter sometimes referred to as “display unit”) 14 driven by the panel drive unit 12, a display control unit (display control device) 16 that controls image display in the display device, and a light source device 18 disposed on the back surface of the liquid crystal panel (display unit) 14.

The light source device 18 includes a circuit board (or light source board) 50 on which light sources (in other words, light source elements such as LEDs) are mounted, which is provided on the back surface side of the liquid crystal panel (display unit).

A circuit board 50 is mounted on the light source device 18. The light source device 18 includes a backlight unit 20.

The backlight unit 20 includes a light source mounting region 22 where light sources (as a specific example, LED (Light-Emitting Diode), etc.) are mounted on the circuit board 50, at least one temperature detection unit (as a specific example, a temperature detection unit 32 including a thermistor 31) 32 provided outside the light source mounting region 22 (outside a predetermined end portion of the light source region 22), a light source control unit 34 (equipped with a light source drive unit 35), and a temperature suppression unit 36. Note that this temperature suppression unit 36 may be provided, for example, within the display control unit (display control device) 16.

The light source mounting region 20 has a rectangular (quadrilateral) shape in a plan view seen from the upward direction (+Z direction).

Also, in the light source mounting region 22, a light source group 24 composed of a plurality of light sources (LEDs, etc.) 25 provided (specifically, surface-mounted) on the circuit board 50, a thermal pattern 26, and a cooling element (here, a Peltier element) 28 as a countermeasure element to suppress temperature rise of the light sources 25 are provided. The thermal pattern 26 includes main parts 26a and 26b that collect heat generated by light emission of at least one light source at an arbitrary position, among the plurality of light sources 25, and a connection part 26c that is thermally connected to the temperature detection unit (including the thermistor 31) 32 and transmits the heat collected to that temperature detection unit 32.

In the example of FIG. 1, the main parts 26a and 26b of the thermal pattern can be called “branch wirings or branch patterns” branched from the connection part 26c.

Note that the main part of the thermal pattern may be a planar solid pattern, and in this case, the planar solid pattern may, for example, collectively collect the heat of all LEDs in the light source mounting region and transmit it to the connection part 26c.

As the thermal pattern 26, for example, copper (or an alloy with nickel, iron, etc.) having excellent thermal conductivity can be used.

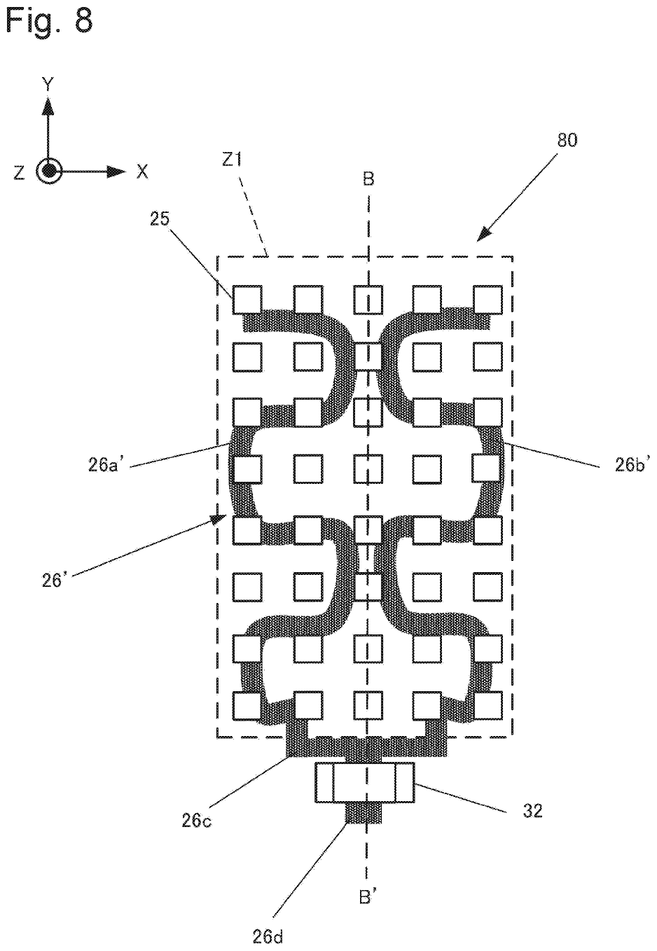

“The branch wirings 26a and 26b as the main part of the thermal pattern” can be called “a part (in other words, a heat collection part) whose main role is heat collection, extending from the side of the second end portion opposite to the first end portion, which is the side where the temperature detection unit 32 is provided in the light source mounting region 22, to the side of the first end portion”. The shapes of the branch wirings 26a and 26b as the main part of the thermal pattern 26 are linear in the example of FIG. 1, but are not limited to this and may be curved shapes (this point will be explained using FIG. 8).

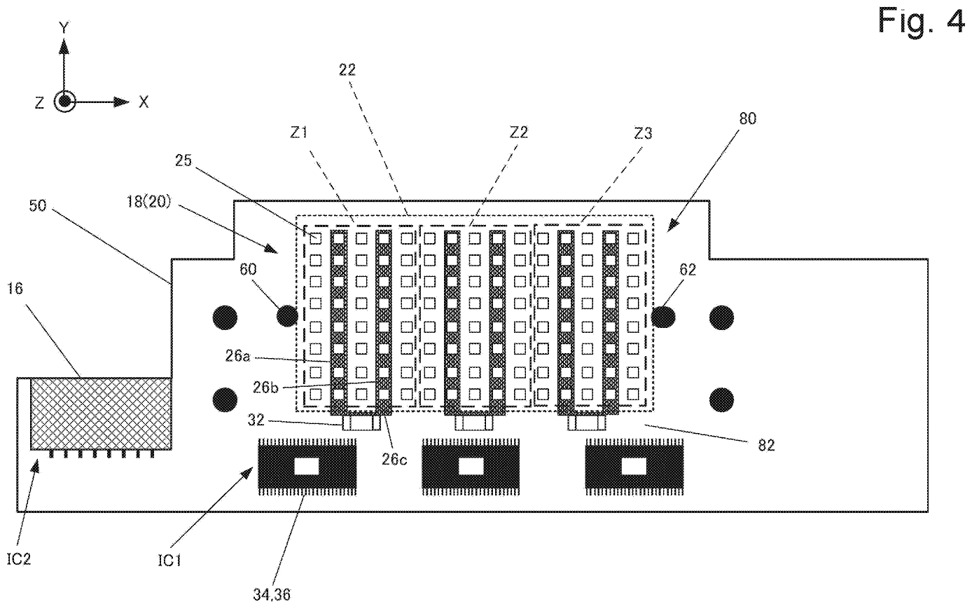

Also, the “connection part 26c” can be called “a part whose main role is to thermally connect the above-mentioned main parts 26a and 26b and the temperature detection unit 32, and transmit the collected heat to the temperature detection unit 32”. The shape of this connection part 26c can be set to an appropriate shape according to the relative positional relationship between the temperature detection unit (thermistor, etc.) 32 and the thermal pattern 26. Details of the thermal pattern 26 will be explained in FIG. 4 to FIG. 7.

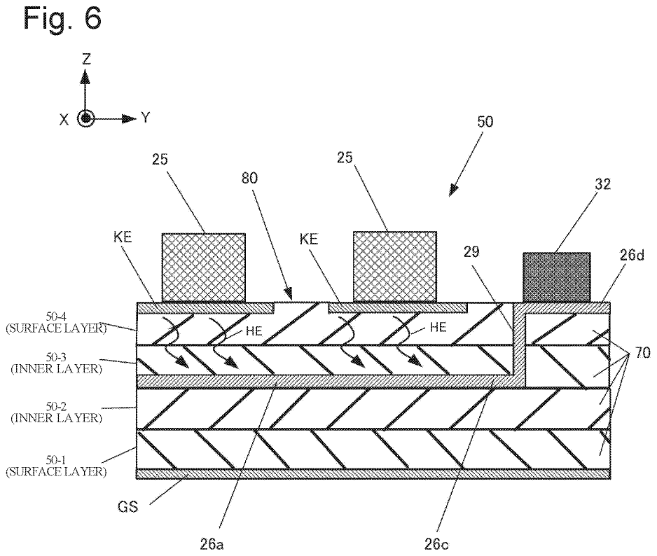

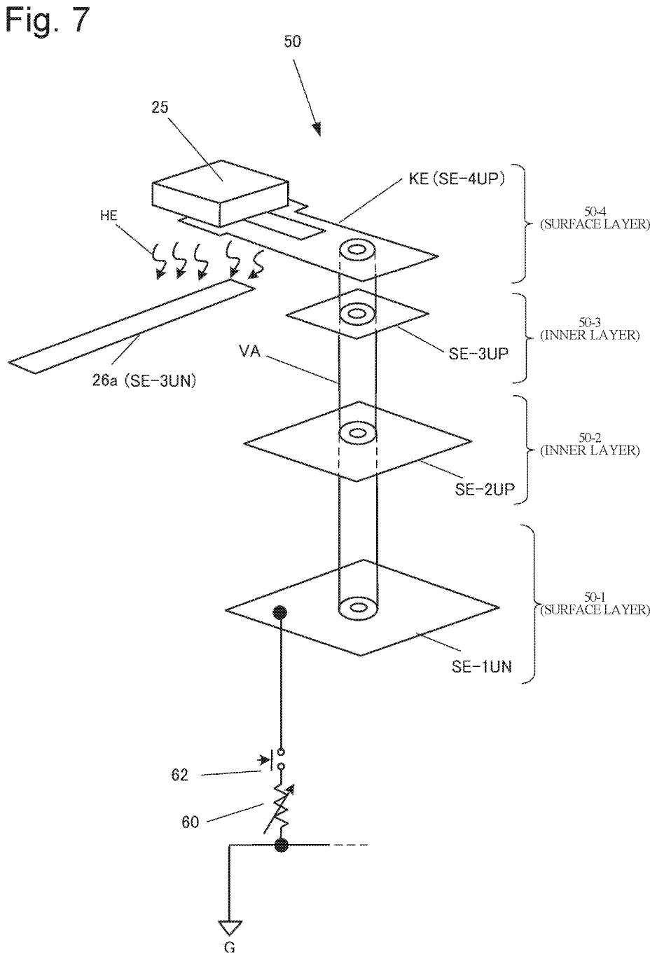

Also, as the circuit board 50, for example, a multilayer FR-4 substrate excellent in heat resistance, etc., can be used (details of this point will be explained using FIG. 6 and FIG. 7).

The multilayer FR-4 substrate as the circuit board 50 can have a surface layer and at least one inner layer. The inner layer is disposed below the surface layer via an electrical insulating layer (an electrical insulating layer whose main materials are glass fiber cloth and epoxy resin). Note that as the inner layer pattern provided in the inner layer, an upper pattern on the mounting surface side and a lower pattern on the back surface side opposite to the mounting surface can be provided.

The main parts 26a and 26b of the thermal pattern 26 are wired as the above-mentioned inner layer patterns so as to overlap the light source mounting region 22 in a plan view seen from above (+Z direction).

In other words, the thermal pattern 26 (main parts 26a and 26b of the thermal pattern) can be provided directly under each light source (for example, each LED) 25. In this case, in a plan view seen from above, at least a part of the thermal pattern will have an overlap with the light source (LED) 25.

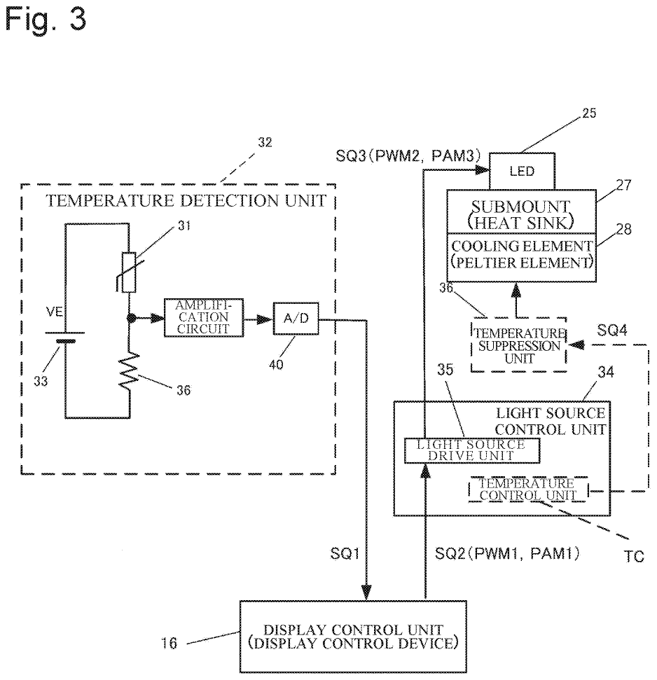

Therefore, even if the position of the temperature detection unit 32 and the position of the light source (LED, etc.) as a heat source 25 are separated, heat generated from that light source (LED) 25 can be efficiently collected through an electrical insulating layer (not shown in FIG. 1, reference numeral 70 in FIG. 3) and efficiently (in other words, reducing heat loss) transmitted to the temperature detection unit 32 by the thermal pattern 26.

Therefore, even if the temperature detection unit 32 is disposed outside the light source mounting region 22, the temperature of the light source 25 or the circuit board 50 can be detected (estimated) with high accuracy. Therefore, in a light source device, it becomes possible to simplify the mounting of the temperature detection unit 32 and improve the accuracy of temperature measurement.

Also, light sources (LEDs, etc.) 25 are disposed on the mounting surface of the circuit board 50, but no light sources 25 are disposed in the inner layer located below the surface layer of the circuit board 50, and since there is much empty space, there is a high degree of freedom in disposing the thermal pattern 26.

Therefore, it is possible to provide a pattern (optimal pattern) with higher heat collection and heat transfer performance in consideration of the state of mounting of the light sources 25, for example, the shape of the light source mounting region 22, the arrangement of the light sources 25, the density of the arrangement of the light sources 25, the arrangement situation of signal lines and grounds supplying signals to the light sources 25, etc.

Therefore, the shape of the branch lines 26a and 26b as the main part of the thermal pattern 26 seen from above may be linear as shown in FIG. 1, and may also be curved as shown in FIG. 8. Also, the width and length of straight lines, the degree of bending, width, and length of curves, etc., of the branch lines 26a and 26b can be determined relatively freely.

The temperature detection unit (having a thermistor 31, etc.) 32 detects (estimates) the temperature of the light source 25 or the circuit board 50 based on the temperature of the thermal pattern (thermal wiring) 26. The light source control unit 34 performs predetermined countermeasure processing based on the detected temperature.

An example of the control procedure in the countermeasure processing is as follows.

The thermistor 31 as a temperature detection element included in the temperature detection unit 32 constantly measures the temperature of the thermal pattern 26 and supplies a temperature detection signal SQ1 to the display control unit (display control device) 16 (Step S1).

The display control unit (display control device) 16 transmits a light emission control signal SQ2 that controls light emission state of the light source (LED) 25 to the light source control unit 34 based on the temperature detection signal SQ1, and the display control unit (display control device) 16 determines whether the temperature of the light source 25 or the circuit board 50 has exceeded a predetermined threshold value (Step S2).

If it exceeds the threshold value, heat countermeasure processing to suppress deterioration, etc., of the light source 25 due to temperature rise becomes necessary, so the light source control unit 34 that has received light emission control signal SQ performs predetermined heat countermeasure processing (Step S3).

There are various types of this countermeasure processing; for example, from the viewpoint of light source protection, derating processing (processing to drive the light source with a current (or voltage) lower than the rated value to suppress light emission) may be performed, or cooling means such as a fan or a cooling element may be used to cool the light source, or the brightness or output of the light source may be optimized to minimize power consumption while maintaining the necessary amount of light emission. Note that in the above countermeasure processing, the above-mentioned each processing may be used in combination with processing that issues a warning, etc.

In the embodiment of FIG. 1, as heat countermeasure processing, the light source drive unit 35 included in the light source control unit 34 supplies a light source drive control signal SQ3 to the light source group 24 to strengthen the derating of the light source, and in combination with this, it is possible to use a cooling element 28 (for example, a Peltier element) to cool the light source 25 (or the circuit board 50) and suppress temperature rise. It is also possible to perform processing to optimize the brightness or output of the light source 25 and minimize power consumption while maintaining the necessary amount of light emission. Note that the cooling element 28 (for example, a Peltier element) may be omitted.

When using the cooling element 28, the light source control unit 34 supplies a control signal SQ4 for temperature suppression to the temperature suppression unit 36, and in response to this, the temperature suppression unit 36 drives (starts) the cooling element (Peltier element) 28.

Also, when adopting a method of optimizing the brightness or output of the light source 25, the light source drive unit 35 provided in the light source control unit 34 supplies the light source drive control signal SQ3 to the light source group 24 to suppress the brightness, etc., of the control target light source 25.

Note that when the temperature of the light source 25 (circuit board 50) becomes equal to or lower than a predetermined threshold value, the light source control unit 34 performs processing such as interrupting the heat countermeasure processing or reducing the degree of the heat countermeasure processing (including returning to the initial state) (Step S4).

Also, when adjustment of the brightness, etc., of the light source 25 is performed due to the temperature rise of the light source 25, the light source control unit 34 may supply a notification signal indicating that to the display control unit (display control device) 16.

The display control unit (display control device) 16 and the panel drive unit 12 are transmitting and receiving control signals SQ5 and SQ6 to and from each other. The panel drive unit 12 that has received the above-mentioned notification signal SQ5 determines whether it is necessary to adjust the brightness, etc., of the display image in accordance with the suppression processing of the brightness, etc., of the light source 25. If necessary, it supplies a liquid crystal drive signal (including a liquid crystal control signal) SQ7 to the liquid crystal panel (display unit) 14 to adjust the brightness, etc., of the display image as appropriate.

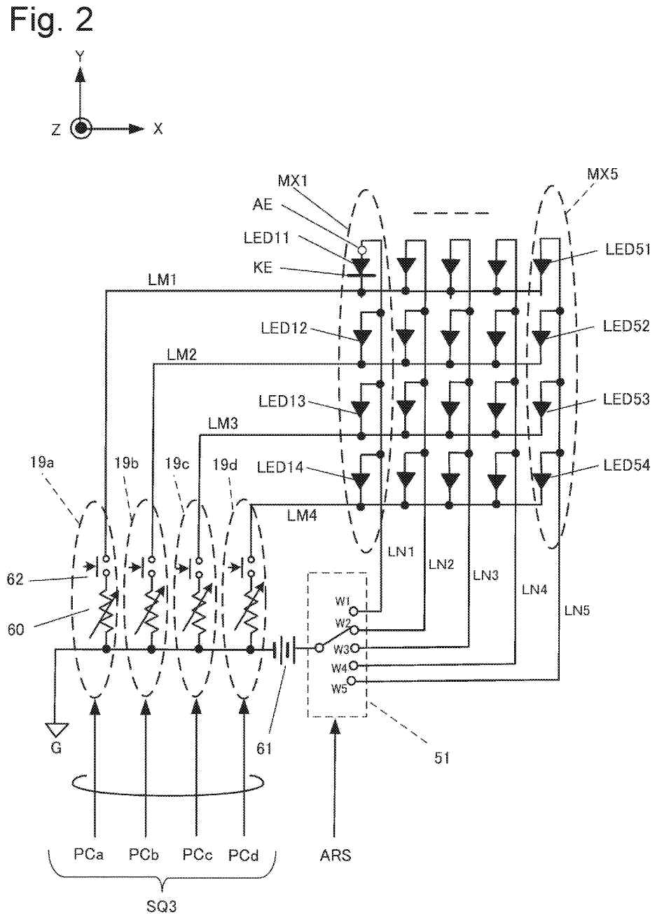

The following explanation refers to FIG. 2. FIG. 2 is a diagram showing an example of a configuration for driving each light source (LED) in a light source device employing a local dimming driving method. In FIG. 3, the same reference numerals are given to parts common to the previously shown drawings.

In FIG. 2, a total of 20 LEDs (LED11 to LED54) are arranged in a 5-column 4-row matrix.

The anode AE of each LED (LED11 to LED54) (see LED11) is connected to scan lines (LN1 to LN5), and the cathode KE (see LED11) is connected to signal lines (LM1 to LM4).

Each of the signal lines (data lines) LM1 to LM4 is connected to each of LED dimming units 19a to 19d, and dimming control signals PCa to PCd are input to each of the LED dimming units 19a to 19d. The above-mentioned dimming control signals PCa to PC are included in the light emission drive control signal SQ3 described earlier in FIG. 1.

Each LED dimming unit 19a to 19d is provided with a variable resistor 60 for controllably varying the constant current amount in LED driving, and a PWM switch 62 (for example, composed of a MOS transistor (MOSFET)) for generating pulses that are pulse-width modulated (PWM pulses). The resistance value of the variable resistor 60, the switching time and switching timing of the PWM switch 62, etc., are controlled by the dimming control signals PCa to PCd.

Also, one end of the variable resistor 60 is grounded.

LED11 to 54 are divided into regions MX1 to MX5 corresponding to each of the scan lines LN1 to LN5.

An area selection switch 51 equipped with contacts W1 to W5 is provided to sequentially select each region MX1 to MX5 by the scan lines LN1 to LN5. When one contact (any of W1 to W7) is selected in the area selection switch 51, the scan line corresponding to that contact (any of LN1 to LN5) is connected to a power source (battery) 61 via that contact, and a power source voltage is supplied to the scan line. Thereby, the LEDs whose anode AE is connected to that scan line are forward-biased and a forward voltage is generated, and those LEDs emit light. The brightness (light emission brightness) of the LEDs can be controlled by the constant current amount determined by the resistance value of the variable resistor 60 and the pulse width of the PWM pulse determined by the opening and closing of the PWM switch 62.

The following explanation refers to FIG. 3. FIG. 3 is a diagram showing an example of a configuration of a circuit that controls temperature in a case where a thermistor is used as a temperature detection unit and a cooling element is used for temperature suppression.

A resistor 36 is connected in series to a reference voltage source 33 to the thermistor 31 included in the temperature detection unit 32.

Here, the thermistor 31 functions as a type of variable resistor whose resistance changes with respect to temperature. Each of the thermistor 31 and the resistor 36 functions as a voltage-dividing resistor that divides the reference voltage VE generated by the reference voltage source 33.

The voltage obtained by voltage division (detection voltage) is amplified by an amplification circuit 38 provided in the light source drive unit 35 included in the light source control circuit 34, and is converted into a digital signal (temperature detection signal) SQ1 by an A/D converter 40.

That converted digital signal (temperature detection signal) SQ1 is supplied to the display control unit (display control device) 16.

The display control unit (display control device) supplies a light source control signal SQ2 to the light source control unit 34 (specifically, the light source drive unit 35) based on the temperature detection signal SQ1. This light source control signal SQ2 includes a first pulse width control signal PWM1 that controls the opening and closing time of the MOSFET as the PWM switch 62 shown earlier in FIG. 2, and a first variable resistance value control signal (PAM1) that controls the variable resistance value of the variable resistor 60.

The light source drive unit 35 supplies a second pulse width control signal PWM2 and a second variable resistance value control signal (PAM2) to the LED as the light source 25 based on the supplied light source control signal. Note that PWM2 and PAM2 may be the same signals as PWM1 and PAM1.

Also, the light source control signal SQ2 can include a judgment signal indicating the necessity of countermeasure processing for temperature suppression.

When it is judged that temperature suppression is necessary, the temperature control unit TC included in the light source control unit 34 supplies a control signal SQ2 for temperature suppression to the temperature suppression unit 36. In response to this, the temperature suppression unit 36 drives (starts) the cooling element (Peltier element) 28.

The LED as the light source 25 is placed on, for example, a submount (or heat sink) 27 with high thermal conductivity, and when the cooling element (Peltier element) 28 is driven (started), the LED 25 is cooled via the submount (or heat sink) 27, and the temperature of the LED 25 is suppressed.

The following explanation refers to FIG. 4. FIG. 4 is a diagram showing an example of a layout configuration (layout configuration corresponding to local dimming driving) on a mounting surface of a circuit board in which a configuration for transmitting heat to a temperature detection unit using a thermal pattern is adopted. Note that in FIG. 4, the same reference numerals are given to parts common to FIG. 1.

In FIG. 4, a light source device 18 and a backlight unit 20 are provided on a circuit board 50. In the light source device 18 (backlight unit 20), the light source mounting region 22 is divided into three divided regions Z1 to Z3 corresponding to local dimming driving.

In each divided region Z1 to Z3, light sources (LEDs) 25 are arranged in a matrix (grid). The matrix can be expressed by a 5-row 8-column matrix. Note that in a plan view seen from above (+Z direction), the light source

mounting region 22 and each divided region Z1 to Z3 have a rectangular (quadrilateral) shape.

For example, in the divided region Z1, main parts 26a and 26b of the thermal pattern 26 are provided in parallel with each other.

Each main part 26a and 26b extends linearly along the column direction of the matrix from the second end portion, which is the end portion opposite to the first end portion, which is the side where the temperature detection unit (thermistor) 32 is provided, to the first end portion in the light source mounting region 22 (or divided region Z1).

Also, the connection part of the thermal pattern 26 commonly connects the main parts 26a and 26b of the two thermal patterns (branch wirings 26a and 26b), and the commonly connected part is thermally connected to the temperature detection unit 32.

In other words, the light source mounting region 22 is divided into a plurality of rectangular divided regions Z1 to Z3 so as to correspond to local dimming driving of the plurality of light sources 25, the temperature detection unit 32 is disposed outside a predetermined end portion (the first end portion on the side close to the temperature detection unit 32) of each divided region Z1 to Z3 in each of the divided regions Z1 to Z3, and the end portion of the branch wirings 26a and 26b as the main part of at least one thermal pattern 26 on the temperature detection unit 32 side is thermally connected to the temperature detection unit 32 via the connection part (connection pattern) 26c.

As explained earlier, in the conventional technology, when adopting a local dimming driving method, light sources 25 at arbitrary positions are lit in accordance with the displayed image, so if the position of the light source 25 emitting light is far from the temperature detection unit 32, heat may not be sufficiently transferred to the temperature detection unit 32, potentially delaying the implementation timing of heat generation countermeasures or decreasing the accuracy of the heat generation countermeasure processing.

According to the configuration of FIG. 4, the above-mentioned conventional problem is resolved. Also, in the configuration of FIG. 4, since heat can be efficiently transmitted to the temperature detection unit 32 via the thermal pattern 26 with high thermal conductivity, the temperature detection unit 32 can be disposed outside a predetermined end portion (the first end portion) of the light source mounting region 22, and the layout related to the arrangement of the temperature detection unit 32 is also simplified.

Note that regarding the above-mentioned “predetermined end portion (it can also be rephrased as the first end portion, or a predetermined boundary line)”, specifically, one of the four sides of the rectangle (quadrilateral), or the vicinity of that side, can be the predetermined end portion (or, a predetermined boundary line).

One temperature detection unit 32 is provided for each divided region Z1 to Z3. This temperature detection unit 32 is provided at a position corresponding to the center position in the left-right direction of the above-mentioned first end portion, outside the light source mounting region 22. The above configuration is the same for the divided regions Z2 and Z3.

Also, an IC1 (integrated circuit) is provided for each divided region Z1 to Z3 on the circuit board 50, and also an IC2 (integrated circuit) is provided. The light source control unit 34 and the temperature suppression unit 36 described in FIG. 1 are integrated in the IC1. The display control unit (display control device) 16 shown in FIG. 1 is integrated in the IC2. Also, a plurality of vias 60, 62, etc., are provided on the circuit board 50.

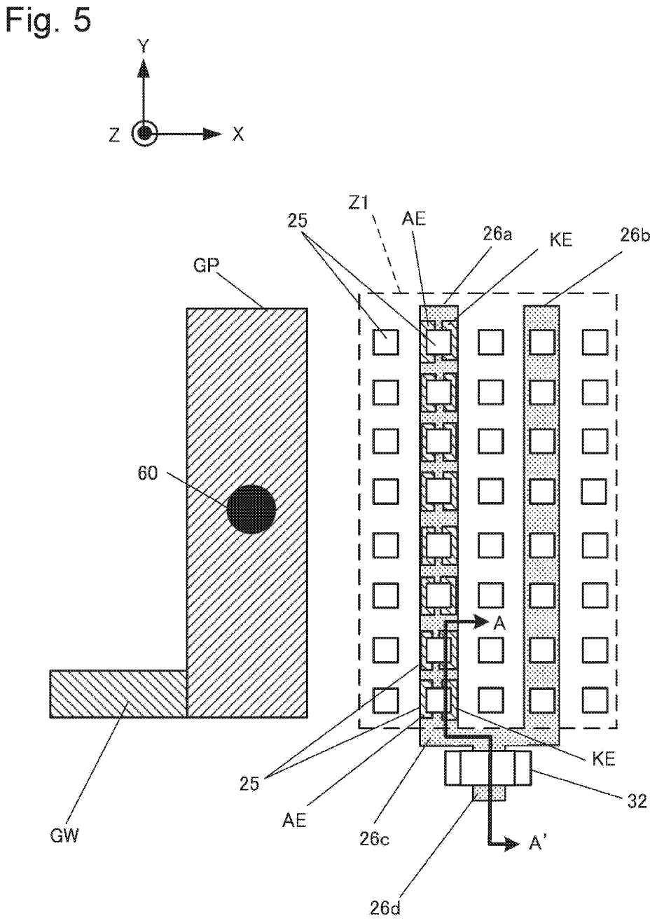

For example, the via 60 is provided to ensure electrical connection of a ground plane (not shown in FIG. 4, reference numeral GP in FIG. 5), and the via 62 is provided to ensure electrical connection of the cathode KE of the LED as the light source 25 provided on the mounting surface, for example (see FIG. 7).

Next, the concrete arrangement mode of the thermal pattern 26 will be explained.

In FIG. 4, as explained earlier, in each divided region Z1 to Z3, light sources (LEDs) 25 are arranged in a matrix (grid), and the above matrix can be expressed by a 5-row 8-column matrix.

The light sources 25 (referred to as “first light sources”) corresponding to the rows of the matrix of the 2nd row and 4th row (one column each) in each divided region Z1 to Z3 overlap with the entirety (may be a part) of the branch wirings 26a and 26b as the main part of the linear thermal pattern 26 in a plan view seen from above (+Z direction).

In other words, the branch wirings 26a and 25b as the main part of the thermal pattern 26 overlap only with the “first light sources” among the plurality of light sources 25 (the entirety or a part may be overlapped). This means that the branch wirings 26a and 26b are provided directly under those light sources 25 for the above-mentioned “first light sources 25”. Since the branch wirings 26a and 26b are provided directly under the light sources 25 via an electrical insulating layer (reference numeral 70 in FIG. 5), heat generated by the light sources 25 is efficiently transmitted to the branch wirings 26a and 26b functioning as heat collection parts located directly under the light sources 25, and therefore, the heat collection property of the thermal pattern 26 is improved.

On the other hand, the light sources 25 corresponding to the rows of the matrix of the 1st row, 3rd row, and 5th row(one column each) among the plurality of light sources 25 do not have an overlap with the above-mentioned branch wirings 26a and 26b. These light sources 25 are referred to as “second light sources”.

Here, the arrangement of each of the above-mentioned matrix-like light sources 25 is regular, and the pitch (interval) between one light source 25 and the light source 25 adjacent to it is in principle the same.

Therefore, the branch wirings 26a and 26b as the main part of the thermal pattern 26 are arranged such that the shortest distance between the light sources 25 corresponding to the above-mentioned “second light sources” and the branch wirings 26a and 26b as the main part of the thermal pattern 26 is in principle the same, or even if there are some exceptions, the branch wirings 26a and 26b as the main part of the thermal pattern 26 are arranged such that the shortest distance falls within a predetermined tolerance range.

In other words, for the above-mentioned “second light sources”, although they do not have an overlap with the branch wirings 26a and 26b, they are arranged such that the shortest distance between the light sources 25 corresponding to the “second light sources” and the branch wirings 26a and 26b is the same (in other words, equidistant), or the shortest distance between the branch wirings 26a and 26b for each light source 25 falls within a predetermined tolerance range.

This can be rephrased as meaning that for the above-mentioned “second light sources”, the variation in the shortest distance between the light source 25 and the branch wirings 26a and 26b as the main part of the thermal pattern 26 in a plan view seen from above (+Z direction) falls within a predetermined tolerance range.

Therefore, it is possible to suppress (for example, minimize) the variation in heat collection property when the branch wirings 26a and 26b as the main part of the thermal pattern collect heat generated from each light source 25.

Note that although the distance to the temperature detection unit 32 fluctuates according to the position of each light source 25, the thermal pattern 26 is composed of materials such as copper and its alloys with high thermal conductivity, and the resistance in thermal conduction is extremely small, so the fluctuation in the above-mentioned distance can be substantially ignored.

Therefore, according to the configuration of FIG. 3, even if each light source 25 were to emit light and generate heat independently, the heat of that light source 25 can be transmitted to the temperature detection unit 32 with high accuracy (in other words, accurately).

Also, the above-mentioned 5-row 8-column matrix can be called, in a broader sense, an m-row n-column (m is an integer of 4 or more, n is an integer of 2 or more) matrix.

In this matrix, in the example of FIG. 4, linear branch wirings 26a and 26b are disposed such that all or a part (preferably all) of the branch wirings 26a and 26b as the main part of the thermal pattern 26 overlap only with the light sources 25 corresponding to the m-th row of the matrix where m is a multiple of 2 (for example, when m is 2, the matrix of the 2nd row).

The light sources corresponding to the rows of the matrix of the 2nd row, 4th row (the same applies hereinafter) correspond to the “first light sources” explained earlier. Branch wirings 26a and 26b as the main part of the thermal pattern 26 exist directly under these light sources 25, and for those light sources 25, the heat generated from each light source 25 is transmitted to the branch wirings 26a and 26b at the shortest distance via the electrical insulating film (reference numeral 70 in FIG. 6), so efficient heat collection is realized.

On the other hand, the light sources 25 corresponding to the rows of the matrix of the 1st row, 3rd row, 5th row (the same applies hereinafter) correspond to the “second light sources” explained earlier. As explained earlier, in a plan view seen from above (+Z direction), the shortest distance between each light source 25 and the branch wirings 26a and 26b as the main part of the thermal pattern 26 disposed in the vicinity is the same (equidistant), and each light source 25 is equally disposed in the vicinity of the main parts 26a and 26b of the branch wiring 26, so there is no variation regarding heat collection for each light source 25, and efficient heat collection is possible for any light source 25.

Also, there may be a case where a slight difference occurs in the above-mentioned shortest distance due to some circumstances (for example, layout convenience with other wirings (ground lines or signal lines)). However, as explained earlier, as long as the variation in each shortest distance is within a predetermined tolerance range, it is possible to suppress (for example, minimize) the variation in heat collection property when the thermal pattern 26 collects heat generated from each light source 25.

Therefore, according to the arrangement example of the thermal pattern in FIG. 4, the temperature rise of the circuit board 50 (or each light source 25) due to heat generation of the light source 25 can be detected with high accuracy (accurately) regardless of the position where the light source 25 is disposed.

In other words, even if light sources 25 in a partial region at an arbitrary position in the light source mounting region 22 emit light locally, the temperature rise of the circuit board 50 due to that local heat generation can be detected with high accuracy (accurately) regardless of the relative positional relationship between the partial region and the light source mounting region 22.

Therefore, according to the arrangement example of the thermal pattern 26 in FIG. 3, it becomes possible to perform highly accurate countermeasure processing capable of suppressing the temperature rise at an appropriate timing.

Also, in FIG. 4, on the mounting surface 80 of the circuit board 50, an IC1 equipped with a light source control unit 34 that controls driving of the plurality of light sources 25 is provided in addition to the light source mounting region 22, and one temperature detection unit 32 (depending on the situation, a plurality of temperature detection units 32) is provided in an empty region 82 between the light source mounting region 22 and the IC1 equipped with the light source control unit 34. In other words, at least one temperature detection unit 32 is provided in an empty region (empty space) 82 between the light source mounting region 22 and the light source control unit 34 on the mounting surface 80.

According to this layout configuration, heat generated in the light source mounting region 22 can be efficiently transmitted to the temperature detection unit 32 using a thermal pattern 26 with high thermal conductivity, and furthermore, that heat can be efficiently transmitted to the light source control unit 34 provided in the vicinity of the temperature detection unit 32. Therefore, based on highly accurate temperature detection results, highly accurate countermeasure processing for temperature suppression can be performed at an appropriate timing.

Also, according to the above layout configuration, since the empty region 82 in the circuit board 50 is used, mounting of devices with high integration (in other words, a small circuit board 50 with little useless empty space) can be realized.

Also, in FIG. 4, in a plan view seen from above (+Z direction), the thickness of the pattern in the branch wirings 26a and 26b as the main part of the thermal pattern 26 is depicted as approximately equivalent to the width of each of the plurality of light sources 25 in the direction corresponding to the thickness of the branch wiring 26.

However, it is not limited to this, and depending on the situation, the thickness of the pattern in the branch wirings 26a and 26b may be set narrower than the width of the light source (light source device) 25.

As explained earlier, in recent years, higher integration of light sources 25 has progressed, and the pitch between light sources 25 tends to become narrower. Also, there is a possibility that a ground plane (reference numeral GP in FIG. 5) or wiring for connection with signal lines, or through-vias (or contact electrodes, etc.: reference numeral VA in FIG. 7) may be provided at arbitrary positions in the lower layer plane in the inner layer of the circuit board 50.

Even in such a case, if the width of the branch wirings 26a and 26b is set narrower than the width of the light source (light source device) 25, the exclusive area of the thermal pattern 26 becomes small, so it is possible to dispose the thermal plane 26 relatively freely in response to the narrowing pitch of each light source 25 or the decrease in the degree of freedom in the arrangement of the thermal pattern 26 in the lower layer (lower layer plane) of the circuit board.

### Second Embodiment

The following explanation refers to FIG. 5. FIG. 5 is a diagram showing an example of the arrangement of a ground pattern, anode electrodes and cathode electrodes of LEDs, etc., in the layout configuration of FIG. 4 (layout configuration corresponding to local dimming driving). In FIG. 5, the same reference numerals are given to parts common to the previously shown drawings.

In FIG. 5, the ground includes a ground plane GP with a wide wiring width, and a ground line GW that branches from the ground plane GP and has a wiring width narrower than that of the ground plane GP.

In FIG. 5, the ground plane GP is not provided around the branch wirings 26a and 26b as the main part of the thermal pattern 26, and is provided outside the light source mounting region 22.

However, it is not limited to this, and the ground plane GP may be provided at a position (empty region, etc.) away from the branch wirings 26a and 26b as the main part of the thermal pattern 26 within the light source mounting region 22.

As a result, it is prevented that heat generated by the light source 25 escapes to the wide ground plane GP.

Since the heat of the light source 25 is transmitted to the main parts 26a and 26b of the thermal pattern 26 without escaping to the ground plane GP, there is no decrease in heat collection by the main parts 26a and 26b of the thermal pattern 26, and high heat collection is always realized.

Also, in FIG. 5, the patterns of the anode (anode electrode) AE and the cathode (cathode electrode) KE of each light source 25 are drawn.

Note that in FIG. 5, in order to avoid complication of the drawing, the patterns of the anode (anode electrode) AE and the cathode (cathode electrode) KE of each light source 25 are drawn only for the light source 25 at a position corresponding to the branch wiring 26a.

The cathode electrode KE also functions as a heat dissipation member that dissipates heat generated by each light source 25 toward the branch wirings 26a and 26b as the main part of the thermal pattern 26 disposed directly below. Therefore, the heat collection in the branch wirings 26a and 26b is improved.

Note that in FIG. 5, reference numeral 26d is attached to the end portion of the connection part 26c in the thermal pattern 26.

This is because while the connection part 26c is a pattern provided in the inner layer of the circuit board 50, its end portion is a pattern provided on the above-mentioned surface layer, so separate reference numerals are attached (see FIG. 6).

The following explanation refers to FIG. 6. FIG. 6 is a cross-sectional view taken along line A-A′ in FIG. 5.

In the example of FIG. 6, a 4-layer FR-4 substrate is used as the circuit board 50. In FIG. 6, reference numerals 50-1 to 50-4 are attached to the first layer to the fourth layer.

This multilayer (4-layer) circuit board 50 may be capable of having conductive through-members (not shown) that penetrate each layer 50-1 to 50-4 (see reference numeral VA in FIG. 7).

In this case, for example, a conductive pattern GS is provided on the back surface of the first layer.

This conductive pattern GS corresponds, for example, to the signal electrode SE-1UN provided in the first layer in FIG. 7.

Also, in FIG. 6, partial patterning is applied to the electrical insulating layer 70 of the fourth layer 50-4 to form a shallow groove, and a cathode electrode KE is formed within this groove. Note that this cathode electrode KE is formed as an upper pattern of the fourth layer, which is the surface layer.

Also, the branch wiring 26a and the connection part 26c as the main part of the thermal pattern 26 are formed as lower patterns of the third layer 50-3. Since the branch wiring 26 is wired directly under the LED as the light source 25, it can efficiently collect the heat HE generated from the light source 25.

Also, the end portion 26d (in other words, the end portion connected to the temperature detection unit 32) of the connection part 26c is formed as an upper pattern (surface layer pattern) of the fourth layer 50-4.

The connection part 26c and its end portion 26d are (thermally) connected via a contact part 29.

As described above, in FIG. 6, a multilayer (4-layer) FR-4 substrate is used. An FR-4 substrate is generally a circuit board whose main materials are glass fiber cloth and epoxy resin, and has excellent properties in electrical insulation, mechanical strength, thermal stability, flame retardancy, etc. Therefore, the FR-4 substrate contributes to efficient heat conduction by the thermal pattern 26, and can also suppress thermal instability of the circuit board 50 caused by providing the thermal pattern 26, and ensure stable heat detection characteristics.

Also, as described above, a through-member (specifically, a through-via, or a contact electrode embedded in a contact hole, etc.: see reference numeral VA in FIG. 7) can be formed on the multilayered FR-4 substrate.

In recent years, higher integration of light sources (light source elements) 25 has progressed, and from the viewpoint of removing thermal instability in addition to electrical connection to the light sources 25, considerable constraints have arisen regarding the layout of wiring (conductive pattern). Even when the degree of freedom in the layout of wiring (conductive pattern) decreases, according to the structure of FIG. 6, an upper pattern or a lower pattern can be provided in the second layer 50-2 and the third layer 50-3, which are inner layers among the multilayer layers 50-1 to 50-4. Therefore, by effectively using these patterns, it is possible to relatively freely lay out the thermal pattern 26 while eliminating thermal instability. Therefore, it is possible to respond relatively easily to higher integration of the light sources 25.

In a method for manufacturing the above-mentioned multilayer circuit board 50 (in other words, a method for mounting the light source device 18), for example, it includes the steps of providing a plurality of light sources 25 in the light source mounting region 22 in the mounting surface 80 on the circuit board 50, providing at least one temperature detection unit 32 outside the light source mounting region 22 on the mounting surface 80, and providing a thermal pattern 26 including a main part that collects heat generated by light emission of at least one light source 25 at an arbitrary position, among the plurality of light sources 25, and a connection part that is thermally connected to the temperature detection unit and transmits the collected heat to the temperature detection unit 32. A direction perpendicular to the mounting surface 80 of the circuit board 50 is defined as the vertical direction, a direction toward the mounting surface 80 is defined as the upward direction, and a direction opposite to the upward direction is defined as the downward direction. Given the definition above, in the case where the circuit board includes a surface layer on which the plurality of light sources are mounted, and at least one inner layer provided below the surface layer via an electrical insulating film, in the step of providing the above-mentioned thermal pattern 26, the main parts 26a and 26b of the thermal pattern 26 are wired as the above-mentioned inner layer pattern so as to overlap the light source mounting region 22 in a plan view seen from above (transparent plan view in a transparent plan drawing).

### Third Embodiment

The following explanation refers to FIG. 7. FIG. 7 is a diagram showing an example of patterns disposed in each layer of a 4-layer FR-4 substrate. In FIG. 7, under the LED as the light source 25, its cathode electrode KE (SE-4UP) of that LED is disposed as an upper pattern of the fourth layer (surface layer).

Note that the above notation “SE-4UP” indicates that it is an electrode SE provided as an upper pattern (UP) of the fourth layer 50-4.

Also, for example, the branch wiring 26a as the main part of the thermal wiring 26 is denoted as SE-3UN. This indicates that it is an electrode SE provided as a lower pattern (UN) of the third layer 50-3. The same applies to other notations.

A MOSFET 62 as a PWM switch connected in series, and a variable resistor 60, both of which were explained in FIG. 2, are connected to the electrode SE-1UN of the first layer.

In FIG. 7, a through-electrode (through-via) VA electrically connects the electrode SE-1UN, SE-2UP, SE-3UP, and the cathode electrode KE (SE-4UP) of the LED 25 of the fourth layer (surface layer).

Also, as explained earlier, since the cathode electrode KE of the LED as the light source 25 also serves as a heat dissipation plate, an effect is also obtained in that the amount of transmission of heat HE to the branch wiring 26a as the main part of the thermal pattern 26 increases.

### Fourth Embodiment

The following explanation refers to FIG. 8. FIG. 8 is a diagram showing an example of a layout in which branch wirings as the main part of a thermal pattern are curved. Note that in FIG. 8, the same reference numerals are given to parts common to the previously shown drawings.

Also, in FIG. 8, the shape of the thermal pattern 26′ in the divided region Z1 of FIG. 4 explained earlier is shown. A similar shape of the thermal pattern 26 can be adopted in other divided regions Z2 and Z3.

In FIG. 8, the branch wirings 26a′ and 26b′ as the main part of the thermal pattern 26′ are formed in a curved shape in a plan view seen from above (+Z direction) (transparent plan view in a transparent plan drawing).

Light sources (LEDs, etc.) 25 are disposed on the mounting surface 80 of the circuit board 50, but no light sources are disposed in the inner layer of the circuit board 50, and since there is much empty space, there is a high degree of freedom in disposing the thermal pattern 26′.

Therefore, in FIG. 8, it is possible to select the shape of the pattern with high heat collection and heat transfer performance in consideration of the state of mounting of the light sources 25, for example, the shape of the light source mounting region 22, the arrangement of the light sources 25, the density of the arrangement of the light sources 25, the arrangement situation of signal lines and grounds supplying signals to the light sources 25, etc.

As in FIG. 8, when the branch wirings 26a′ and 26b′ as the main part of the thermal pattern 26 are made into a curved shape, the wiring length becomes longer, and it cannot be denied that the transmission efficiency of heat to the temperature detection unit 32 slightly decreases, but by appropriately adjusting the wiring width, the degree of bending of the wiring, etc., it is possible to adjust the ease of heat transfer and suppress the decrease in heat transfer efficiency.

Also, it is important that the curved thermal pattern 26 is equipped with a heat collection performance that collects the heat generated by each light source 25 as equally (uniformly) as possible, regardless of the position of each light source 25 arranged in a planar shape.

In FIG. 8, each of the branch wirings 26a′ and 26b′ as the main part of the thermal pattern 26′ is arranged such that the shortest distance between each of the light sources 25 arranged in a planar shape falls within a predetermined tolerance range.

Also, in FIG. 8, a virtual central line B-B′ extending in the column direction of the matrix of the light sources 25 that bisects the rectangular (quadrilateral) divided region Z1 is assumed. And each of the branch wirings 26a′ and 26b′ as the main part of the thermal pattern 26 is arranged to be line-symmetric with respect to that central line B-B′.

Thereby, the thermal pattern 26 can be equipped with a heat collection performance that collects the heat generated by each light source 25 as equally (uniformly) as possible, regardless of the position of each light source 25 arranged in a planar shape.

As explained above, according to the embodiments of the present invention, in a light source device, it is possible to simplify the mounting of the temperature detection unit and improve the accuracy of temperature measurement.

Also, it is possible to realize a highly reliable display device equipped with the light source device of the embodiment of the present invention and a display unit that displays an image using light emission of the light source device.

In other words, it is possible to realize a highly reliable display device equipped with a light source device (light source unit) capable of effectively protecting the light source (light source in the backlight unit) from deterioration of light emission characteristics or damage to the device due to thermal factors.

Although the present invention has been explained using some embodiments as described above, the present invention is not limited to the above-mentioned embodiments, and various modifications and applications are possible.

For example, as the light source, various light-emitting devices such as organic or inorganic electroluminescence elements, etc., can be used in addition to LEDs.

Also, the present invention can be applied to display devices (light source devices) that do not adopt local dimming driving.

Also, the shape of the light source mounting region is not limited to a rectangle, and may be other polygons, circles, etc.

Also, the material of the thermal pattern is not limited to those whose main material is copper, and various materials with high thermal conductivity may be used.

Also, the shape of the thermal pattern is not limited to the shape explained in the embodiments, and modification, etc., are possible as appropriate. Also, as the temperature detection element provided in the temperature detection unit, a thermocouple, etc., may be used in addition to a thermistor.

Also, although it is preferable that each branch wiring as the main part of the thermal pattern is disposed directly under the light source disposed corresponding to the branch wiring, the meaning of “directly under” is interpreted flexibly and in a broad sense.

The present invention is not limited to the above-mentioned exemplary embodiments, and those skilled in the art will be able to easily change the above-mentioned exemplary embodiments to the extent included in the scope of the claims.

### REFERENCE SIGNS LIST

10: Display device
12: Panel drive unit
14: Liquid crystal panel (display unit)
16: Display control unit (display control device)
18: Light source device
20: Backlight unit
22: Light source mounting region
24: Light source group
26, 26′: Thermal pattern (thermal wiring)
26a, 26a′, 26b, 26b′: Main part of thermal pattern (heat collection part)
26c: Connection part of thermal pattern
26d: End part of the connection part of the thermal pattern (end part provided on the upper side in the inner layer of the circuit board)
27: Submount (heat sink)
28: Cooling element (Peltier element, etc.)
32: Temperature detection unit (thermistor, etc.)
33: Reference voltage source
36: Voltage-dividing resistor
34: Light source control unit
35: Light source drive unit
36: Temperature suppression unit
38: Amplification circuit
40: A/D converter
43: Determination processing unit
50: Circuit board (light source board, mounting board, printed wiring board (PCB))
50-1 to 50-4: First to fourth layers of the 4-layer circuit board (4-layer FR-4 substrate)
51: Area selection switch
60: Variable resistor
61: Battery (voltage source)
62: MOSFET as a PWM switch
70: Electrical insulating layer
80: Mounting surface
82: Empty area (empty space) between the light source mounting region and the light source control unit
IC1, IC2: Integrated circuit
GP: Ground plane
GW: Ground line
VA: Through electrode (via, through-via).

1. A light source device comprising:
a plurality of light sources provided in a light source mounting region on a mounting surface of a circuit board;
at least one temperature detection unit provided outside the light source mounting region on the mounting surface; and
a thermal pattern having a main part that collects heat generated by light emission of at least one light source at an arbitrary position, among the plurality of light sources, and a connection part that is thermally connected to the temperature detection unit and transmits heat from the main part to the temperature detection unit,
wherein when a direction perpendicular to the mounting surface of the circuit board is defined as a vertical direction, a direction toward the mounting surface is defined as an upward direction, and a direction opposite to the upward direction is defined as a downward direction, the circuit board includes a surface layer on which the plurality of light sources are mounted, and at least one inner layer provided below the surface layer via an electrical insulating film, and the main part of the thermal pattern is provided in the inner layer so as to overlap the light source mounting region in a plan view seen from above.

2. The light source device according to claim 1,
wherein in a plan view seen from above, the main part of the thermal pattern has a planar shape, and the main part of the thermal pattern having the planar shape has an overlap with each of the plurality of light sources,
or, in a plan view seen from above, the main part of the thermal pattern has a plurality of branch wirings branched from the connection part, each of the plurality of branch wirings has an overlap with a part or all of a first light source, among the plurality of light sources, which is located above that branch wiring in a relative positional relationship with the first light source, and
a second light source among the plurality of light sources that is not located above that branch wiring and does not have an overlap with the branch wiring is arranged so that the shortest distance between each of the second light sources and the branch wiring is the same, or that the shortest distance is within a predetermined tolerance range.

3. The light source device according to claim 2, wherein in the case where the main part of the thermal pattern has the plurality of branch wirings, each of the plurality of branch wirings has a linear or curved shape in a plan view seen from above.

4. The light source device according to claim 2,
wherein the light source mounting region has a rectangular shape in a plan view seen from above,
the plurality of light sources are arranged in a matrix in the light source mounting region,
the plurality of light sources arranged in the matrix can be expressed by an m-row n-column (m is an integer of 4 or more, n is an integer of 2 or more) matrix, and
in the matrix, all or a part of each of the linear branch wirings overlaps with the first light source arranged corresponding to rows of the matrix whose row number m is a multiple of 2 in a plan view seen from above.

5. The light source device according to claim 1,
wherein the light source mounting region is divided into a plurality of rectangular divided regions so as to correspond to local dimming driving of the plurality of light sources,
in each of the divided regions, the temperature detection unit is disposed outside a predetermined end portion of that divided region, and
an end portion of the connection part of at least one of the thermal patterns on the temperature detection unit side is thermally connected to the temperature detection unit.

6. The light source device according to claim 1,
wherein a ground for grounding each of the plurality of light sources includes a ground plane with a wide wiring width and a ground line that branches from the ground plane and has a wiring width narrower than that of the ground plane, and
the ground plane is (i) not provided around the main part of the thermal pattern, but is provided at a position away from the main part of the thermal pattern within the light source mounting region; or (ii) is provided outside the light source mounting region.

7. The light source device according to claim 1, wherein a cathode electrode of an LED as the light source is, for each of the light sources, provided under that light source as a surface layer pattern provided on the surface layer.

8. The light source device according to claim 2, wherein in a plan view seen from above, a thickness of a pattern in the branch wiring as the main part of the thermal pattern is set narrower than a width of each of the plurality of light sources in a direction corresponding to a thickness of the branch wiring.

9. The light source device according to claim 1, wherein on the mounting surface of the circuit board, a light source control unit that controls driving of the plurality of light sources is provided in addition to the light source mounting region, and one or a plurality of the temperature detection units are provided in an empty region between the light source mounting region and the light source control unit.

10. The light source device according to claim 1, wherein a multilayer FR-4 substrate is used as the circuit board, and the multilayer FR-4 substrate is capable of having a conductive through-member that penetrates each layer.

11. A display device comprising:
the light source device according to claim 1; and
a display unit that displays an image using light emission of the light source device.

12. A method for mounting a light source device, comprising the steps of:
providing a plurality of light sources in a light source mounting region on a mounting surface of a circuit board;
providing at least one temperature detection unit outside the light source mounting region on the mounting surface; and
providing a thermal pattern having a main part that collects heat generated by light emission of at least one light source at an arbitrary position, among the plurality of light sources, and a connection part that is thermally connected to the temperature detection unit and transmits heat from the main part to the temperature detection unit,
wherein when a direction perpendicular to the mounting surface of the circuit board is defined as a vertical direction, a direction toward the mounting surface is defined as an upward direction, and a direction opposite to the upward direction is defined as a downward direction, in the case where the circuit board includes a surface layer on which the plurality of light sources are mounted, and at least one inner layer provided below the surface layer via an electrical insulating film, the step of providing the thermal pattern includes providing the main part of the thermal pattern in the inner layer so as to overlap the light source mounting region in a plan view seen from above.
